(19) United States
(12) Patent Application Publication
(10) Pub. No.: US 2005/0143946 A1
(43) Pub. Date: Jun. 30, 2005

(54) Method and apparatus for head write capability measurement in self test

(75) Inventors: Raghu Gururangan, Pleasanton, CA (US); Maxim Roth, Cupertino, CA (US)

Correspondence Address: FLIESLER MEYER, LLP, FOUR EMBARCADERO CENTER, SUITE 400, SAN FRANCISCO, CA, 94111, US

(73) Assignee: Matsushita Electric Industrial Co., Ind., Kadoma-shi (JP)

(21) Appl. No.: 11/013,866

(22) Filed: Dec. 16, 2004

Related U.S. Application Data
(60) Provisional application No. 60/532,775, filed on Dec. 24, 2003.
(60) Provisional application No. 60/532,609, filed on Dec. 24, 2003.

(51) Int. Cl. G01R 27/28; G11B 5/09

(52) U.S. Cl. 702/117; 360/39

(57) ABSTRACT

A method of determining the write head capacity during self test of a hard disk drive is described. Information related to the dynamic coercivity of the disk service is obtained. In one embodiment, a DC erase condition is produced onto the disk surface. An AC signal is provided to a write head such that a region on the disk surface is put into a state of substantially no direction of magnetization. The AC signal to cause this state will be related to the coercive current. The coercive current can be used to estimate the required write current at low temperatures and thus determine whether to reject the hard disk drive.

### CLAIM OF PRIORITY

This application claims priority to U.S. Provisional Application No. 60/532,775 entitled “Head Write Capability Measurement in Self-Test” filed Dec. 24, 2003, and U.S. Provisional Application No. 60/532,609 entitled “Method of Head Write Capability Self-Test” filed Dec. 24, 2003.

### FIELD OF THE INVENTION

The present invention relates to the testing of rotating media storage devices, such as Hard Disk Drives (HDDs).

### BACKGROUND

Rotating media storage devices are an integral part of computers and other devices with needs for large amounts of reliable memory. Rotating media storage devices are inexpensive, relatively easy to manufacture, forgiving where manufacturing flaws are present, and capable of storing large amounts of information in relatively small spaces.

A typical rotating media storage device uses a rotatable storage medium with a head disk assembly and electronics to control operation of the head disk assembly. The head disk assembly can include one or more disks. In a magnetic disk drive, a disk includes a recording surface to receive and store user information. The recording surface can be constructed of a substrate of metal, ceramic, glass or plastic with a thin magnetizable layer on either side of the substrate. Data is transferred to and from the recording surface via a head mounted on an arm of the actuator assembly. Heads can include one or more read and/or write elements, or read/write elements, for reading and/or writing data. Drives can include one or more heads for reading and/or writing. In magnetic disk drives, heads can include a thin film inductive write element and a magneto-resistive (MR) read element.

Typically, each hard disk drive is tested in a self-test process. Self-test can determine whether the hard disk drive is acceptable or whether it should be rejected. One of the difficulties of producing hard disk drives is that they need to be able to operate over a range of temperatures. Typically, at low temperatures the coercivity of the material on this surface can increase to the extent so that it is difficult to write information on the disk. Tests at low temperature are becoming more common. It is desired to have a less expensive self test which can be used to check for coercivity problems that can occur at low temperatures.

### BRIEF DESCRIPTION OF THE DRAWINGS

FIG. 1 is a diagram of a rotating media storage device of one embodiment of the present invention.

FIGS. 2A and 2B are diagrams illustrate the magnetic flux onto a disk.

FIG. 3 is a diagram that illustrates minor and major hysteresis loops.

FIG. 4 is a diagram that illustrates the read voltage versus the write current for one embodiment of the present invention.

FIG. 5 is a diagram that illustrates the production of a DC erase condition.

FIG. 6 is a diagram that illustrates providing a signal at the coercive current in order to set certain regions into a non magnetic.

FIG. 7 is a diagram that illustrates coercivity versus temperature.

FIG. 8 is a diagram that illustrates the coercive current and write current for three exemplary disk drives.

FIG. 9 is a diagram that illustrates population distribution of disk drive coercive currents.

FIGS. 10A and 10B are diagrams that illustrate the use of a switchable resistive portion on a current supply so that the current supply can be switched between two different modes for a current supply of a write head on a disk drive.

### SUMMARY

One embodiment of the present invention concerns determining information concerning the dynamic coercivity of a disk surface. In one embodiment, this information is obtained by writing a portion of the disk into a DC erased condition. In the DC erased condition, the magnetization is in a single direction. An AC signal is supplied to the write head over the disk. As the AC signal is increased, the magnetization of a portion of the disk in that one direction is reduced. When the AC signal is such that a portion of the disk surface does not have a significant direction of magnetization, the current for the AC signal can be considered to be the coercive current. The coercive current indicates information concerning the head write capability of the hard disk. The coercive current can be used to determine the required write current for the disk drive. In one embodiment, the coercive current at one temperature can be used to determine whether to accept or reject the hard disk by indicating whether the hard disk is likely to fail at low temperatures. In another embodiment, the coercive current can be obtained at two temperatures to produce a determination of the slope of coercive current versus temperature which can then be used to determine whether an unacceptable write current is needed at the low temperature operation.

### DETAILED DESCRIPTION

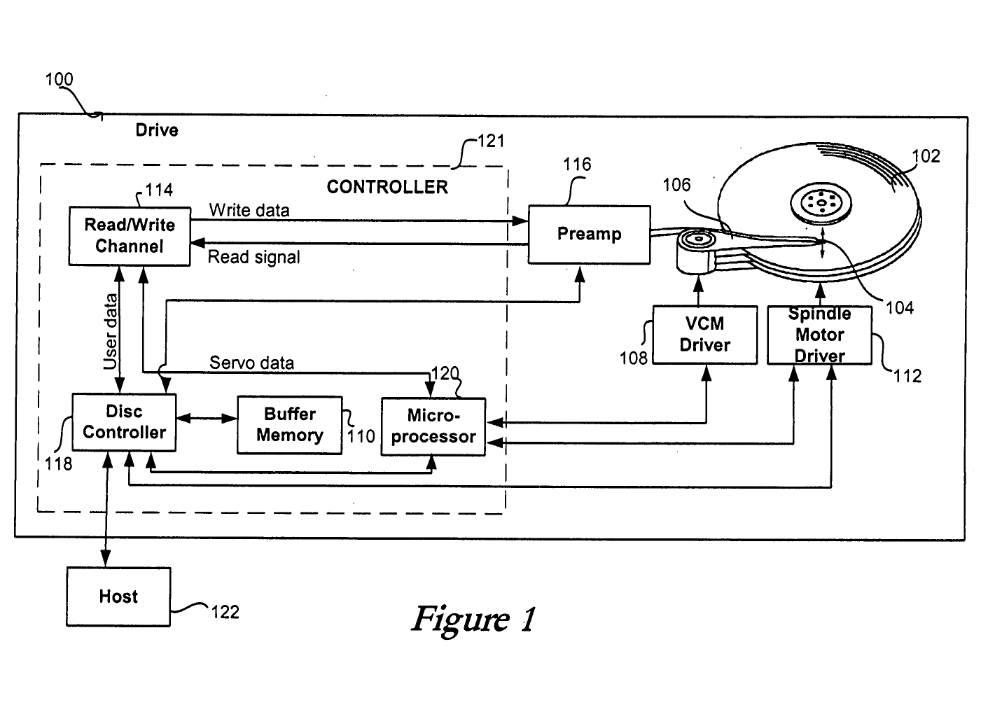

FIG. 1 shows a rotating media storage device 100 that can be used in accordance with one embodiment of the present invention. In this example, the rotating media storage device 100 is a hard disk drive. The rotating media storage device 100 includes at least one rotatable storage medium 102 capable of storing information on at least one surface. Numbers of disks and surfaces may vary by disk drive. In a magnetic disk drive, the storage medium 102 is a magnetic disk. A closed loop servo system, including an actuator arm 106, can be used to position head 104 over selected tracks of disk 102 for reading or writing, or to move head 104 to a selected track during a seek operation. In one embodiment, head 104 is a magnetic transducer adapted to read data from and write data to the disk 102. In another embodiment, head 104 includes separate read elements, such as magnetoresistive (MR) read heads, and write elements. Multiple head configurations may be used.

The servo system can include a voice coil motor driver 108 to drive a voice coil motor (VCM) for rotating the actuator arm 106. The servo system can also include a spindle motor driver 112 to drive a spindle motor (not shown) for rotation of the disk 102. Controller 121 can be used to control the rotating media storage device 100. The controller 121 can include a number of arrangements. In one embodiment, the controller includes a disk controller 128, read/write channel 114, processor 120, and memory 110 on one chip. These elements can also be arranged on multiple chips. The controller can include fewer elements as well.

In one embodiment, the controller 121 is used to control the VCM driver 108 and spindle motor driver 112, to accept information from a host 122 and to control many disk functions. A host can be any device, apparatus, or system capable of utilizing the data storage device, such as a personal computer or Web server. The controller 121 can include an interface controller in some embodiments for communicating with a host and in other embodiments, a separate interface controller can be used. The controller 121 can also include a servo controller, which can exist as circuitry within the drive or as an algorithm resident in the controller 121, or as a combination thereof. In other embodiments, an independent servo controller can be used.

Disk controller 128 can provide user data to a read/write channel 114, which can send signals to a current amplifier or pre-amp 116 to be written to the disk(s) 102, and can send servo signals to the microprocessor 120. Controller 121 can also include a memory controller to interface with external memory.

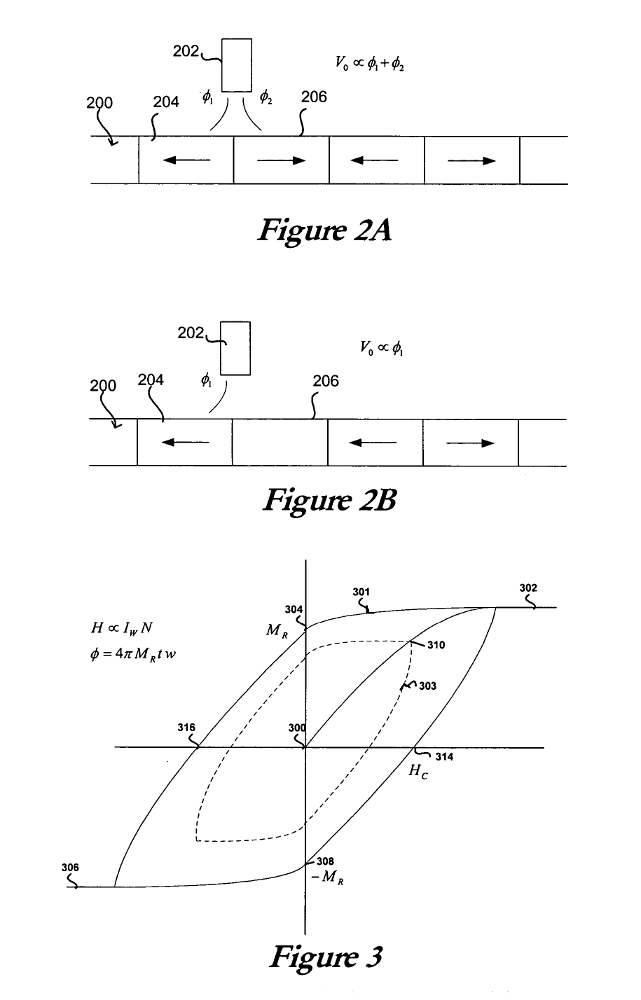

FIG. 2A illustrates reading a disk surface 200 with a magneto-resistive (MR) head 202. In this example the voltage output of the MR head 202 is proportional to the fluxes φ₁ and φ₂. φ₁ being the contribution from the region 204 and φ₂ being the contributions from the region 206. As shown in FIG. 2B, if the contribution from the region 206 is removed by eliminating the flux from region 206, the output V₀ would be proportional to φ₁ alone. By removing the magnetization of region 206, the flux is effectively cut in half.

FIG. 3 illustrates a graph of an applied field H, versus magnetization, M. Starting at point 300 when a magnetic field is supplied, the magnetization can move up to point 302. After removing the applied field, the magnetization will relax to the remnant magnetization point 304. A negative applied field can move the system to point 306. After this field is removed, the system relaxes to the remnant magnetization point 308. When the maximum applied field is used, the magnetization of the disk surface will be the positive remnant magnetization at point 304 or the negative remnant magnetization at point 308. Transition from point 308 to point 304 can be done by increasing the field so that the system moves to point 302 and then relaxes back to point 304.

The applied write field, H, can be produced by suppling a write current into the write head. In one embodiment, the field produced is proportionally to the write current I_{w} and the number of turns in the write head N. The detected flux, φ, is 4πM_{R}tw, where M_{R} is the remnant magnetization, t is the thickness of the coating and w is the width of the track.

In addition to the major hysteresis loop 301 there are also minor hysteresis loops such as loop 303. In loop 303 when the emitted field is moved to a point such as point 310, it then can be relaxed to point 312 with a lesser magnetization than point 304.

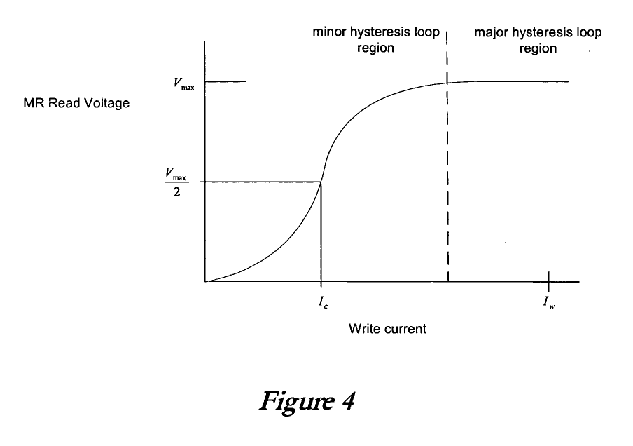

FIG. 4 illustrates a graph of MR read voltage versus write current used to write a potion of the disk. In the major hysteresis loop region, the output will be the maximum, Vₘₐₓ. The read voltage is proportional to the flux which is proportional to the remnant magnetization. In the major hysteresis loop region, the remnant magnetization is constant. For example, looking at FIG. 3, the remnant magnetization is point 304 on the major hysteresis loop. In a minor hysteresis loop region, the remnant magnetization depends upon the write current.

In one embodiment, V=cI_{B} ΔR, where V₀ is the output of the MR read voltage head ΔR is the change in resistance in the MR head due to the detected signal which is proportional to the flux. If a bias current equal to one half of the normal bias current is supplied to the MR read head, the output is one-half of the normal output. In one embodiment, the output of the MR read voltage head cannot be directly determined. Instead the output of the MR read head is supplied to a voltage gain amplifier (VGA), which uses a VGA register to determine how much to amplify the voltage output to some desired value. The VGA register contents will indicate the voltage output, but register indication may not necessarily be linear with respect to the MR read head voltage output. The VGA register value for when the bias current is one half of the normal I_{B} with a normal flux is the same as the VGA register for the normal bias current at half the normal flux since

$$V = c ( \frac{{I}_{B}}{2} ) Δ R = {cI}_{B} ( \frac{Δ R}{2} ) .$$

In one embodiment, a method of testing a disk drive comprises determining information related to the dynamic coercivity of the disk surface. The determining step including suppling an AC signal to a write head over the disk. The method also includes using the information to accept or reject a disk drive. The information can concern the head write capability.

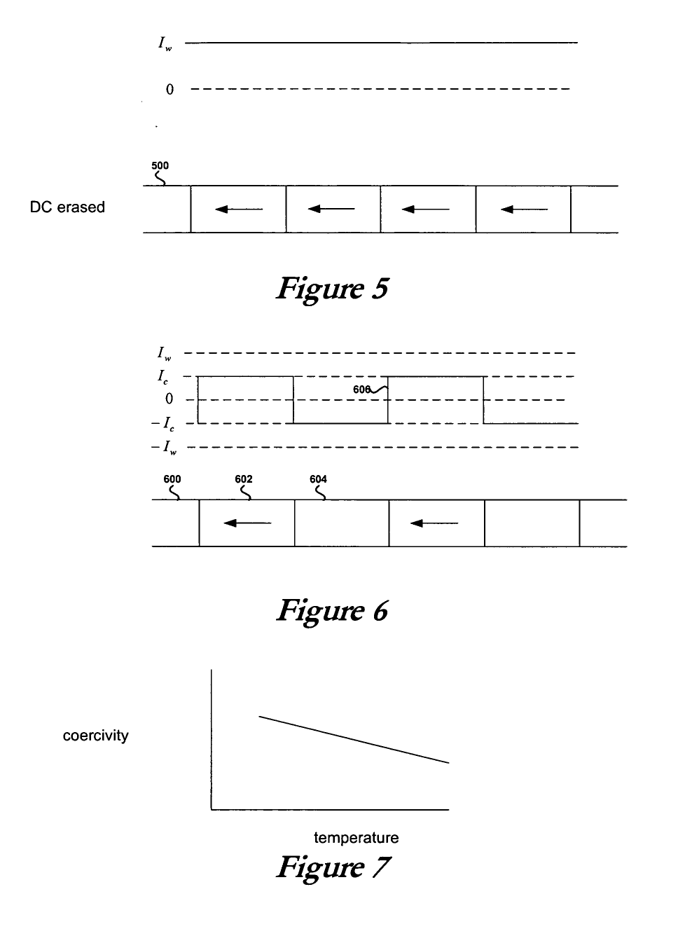

In one embodiment, looking at FIG. 5, the surface 500 is written into a DC erased condition in which the magnetization is in a single direction. Next as shown in FIG. 6, an AC signal supplied to the write head. In this example region 602 is unaffected and region 604 is moved into a state having no significant direction of magnetization. Looking at FIG. 3, this can be done by starting at point 308 and supplying the coercive current to the write head so that the system reaches the point 314 and then relaxing the system back to origin 300. Alternately, starting at point 304, providing a negative coercive write current to move the system to point 316 and then relaxing the system to point 300. The coercive write current causes the emitted field to have the coercive field value, H_{c}. Another way is to first write the AC signal and then DC erase with ever increasing write current (basically the reverse operation).

Looking again at FIG. 6, when the region 604 does not have any direction of magnetization, the detected signal by the MR head positioned in between the region 602 and 604 will be half the maximum output value. In one embodiment the magnitude AC signal to the write head 606 can be ramped up until the detected value of the voltage determined by the VGA register matches the value obtained from the operation shown in FIG. 4.

Alternately, the signal straights can be gotten by doing a Discrete Fourier Transform (DFT) of the signal. Modern disk drives often have DFT capacity of servo burst. The DFT is typically done at 4 samples per cycle and produces an initiation related to the signal intensity. Furthermore, a track average amplitude measurement can be done.

Note that the system of FIGS. 5 and 6 determine values related to the dynamic coercivity rather than the static coercivity. Static coerivity is the coercivity of the disk surface with respect to a constant emitted field. The dynamic coercivity is the coercivity with respect to a changing field. The dynamic coercivity is typically greater than the static coercivity.

The information concerning the coercive current can also be affected not only by the write head shape and other factors. However, these factors also affect the ability to write to the disk surface and thus are useful in accepting or rejecting the hard disk drive. Thus, the information with respect to the signal 606 can be considered to be head write capability information.

FIG. 7 illustrates the diagram that shows how the coercivity increases with decrease in temperature.

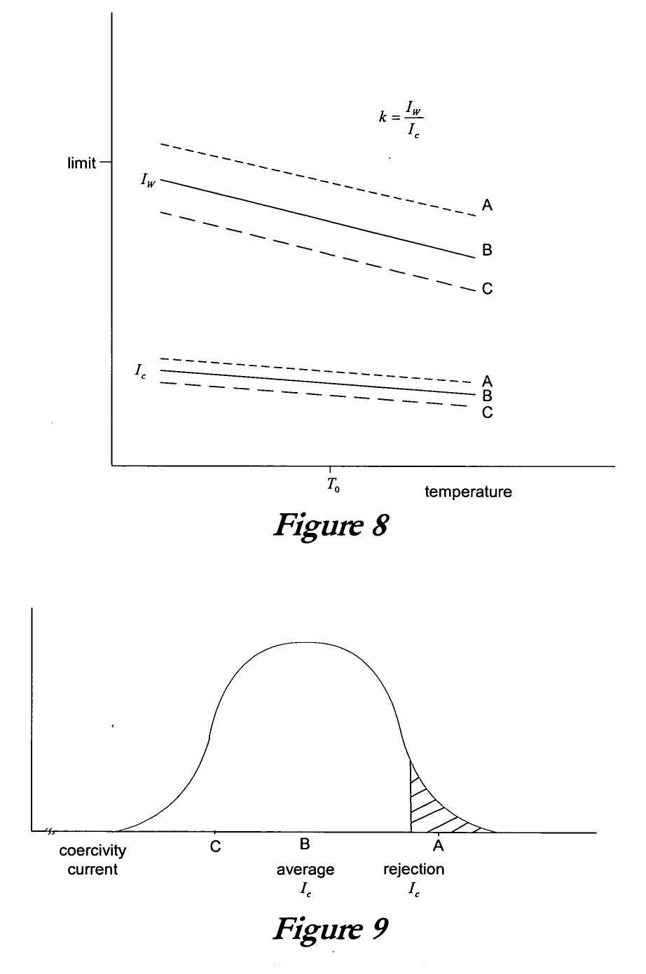

Looking at FIG. 8, as the coercivity increases the required write current also increases. In this example, factor k is equal to the ratio of the required write current over the coercive current and is typically considered to be a constant. Looking at FIG. 8, at temperature T₀, indications of the coercive current can be obtained. This information can be used to estimate the required write current at low temperatures. If the required write current at low temperatures is greater than the limit, as for example A, then the disk drive can be rejected or be tested at low temperature.

The maximum write current is limited since large write currents can negatively affect the write head. As the coercivity of the disk surface is increased to increase the density on the disk drive, the write currents need to be increased reaching the level that high write currents required at low temperatures may adversely affect the write process. Other issues that limit the write current include fringing of the field from the write heads. Such fringing could overwrite other tracks unless the write current is correctly chosen for the coercivity of the magnetic disk medium. Additionally, once the write head starts to become magnetically saturated, increases in write-current will not cause proportional increases in the resulting magnetic field. In the limit of full saturation, increasing the write current will have virtually no effect on the resulting magnetic field.

The determination of the write current values at low temperatures from coercive current information can be done in a number of ways. In one embodiment, a single coercive current value at a single temperature value is used to determine the acceptance or rejection. Predetermined k and slope values can be used to calculate the estimated write current required for the low temperature. In an alternate embodiment, the self test can be done at two different temperatures. This can be used to estimate the slope for the coercive current versus temperature to aid in the estimate of the required write current for low temperatures.

FIG. 9 illustrates an example in which a single coercive current value at a single temperature is used to reject certain test drives. In this example, the rejection coercive current Ic value is used to reject a certain percentage of the disk drives. The disk drives above the rejection Ic can be tested at a lower temperature or just discarded.

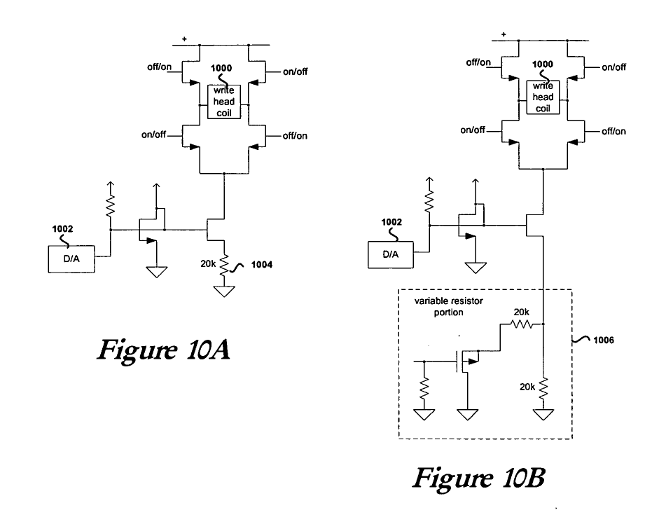

FIG. 10A illustrates a current supply for the write head of a conventional design. In this example, the transistors of the write head are turned on and off in order to produce a negative or positive write current to the write head coil 1000. The magnitude of the write current is determined by the register value supplied through digital to analog (D/A) converter 1002 as well as an external resistor 1004. One disadvantage of the example of FIG. 10A is that the write values supplied by the D/A converter unit 1002 to produce the write current are only linear for a certain range. This range is set by the external resistor 1004. The write range is likely to be too small for both coercive and the write current.

FIG. 10B illustrates a current supply for a write head on a disk drive. The current supply allows two modes. The first mode includes a first current range that includes a standard write current. The second current range being such as it includes the coercive current. In the example of FIG. 10B, switching resistor portions 1006 can be used to switch between a resistance of 10K for the normal operation and 20K for operation in the coercive current range. The use of the switching portion 1006 allows for the operation of the current supply for both the standard and write current range and the coercive current range.

The foregoing description of preferred embodiments of the present invention has been provided for the purpose of illustration and description. It is not intended to be exhaustive or to limit the invention to the precise forms disclosed. Many modifications and variations will be apparent to one of the ordinary skill in the relevant arts. The embodiments were chosen and described in order to best explain the principles of the invention and its practical application, thereby enabling others skilled in the art to understand the invention for various embodiments and with various modifications that are suited to the particular use contemplated. In is intended that the scope of the invention be defined by the claims and their equivalents.

1. A hard disk drive including:
a disk; and
a controller to determine information related to the dynamic coercivity of a disk surface, the determining including supplying an AC signal to a write head over the disk, wherein the information is used to determine whether to accept or reject the disk drive.

2. The hard disk drive of claim 1, wherein the information concerns the head write capability.

3. The hard disk drive of claim 1, wherein the AC signal is such to cause a part of the disk to not have a significant direction of magnetization.

4. The hard disk drive of claim 1, wherein the disk was previously written into a DC erased condition with magnetization in one direction.

5. The hard disk drive of claim 1, wherein the disk was previously written into an AC condition.

6. The hard disk drive of claim 1, wherein the information is the peak current supplied to write head for the AC signal.

7. The hard disk drive of claim 1, wherein the information is the peak current supplied to write head for the DC erased condition.

8. The hard disk drive of claim 1, wherein the information is a peak current is the coercive current.

9. The hard disk drive of claim 8, wherein the coercive current at one temperature is used to estimate whether the disk drive will fail at another temperature.

10. The hard disk drive of claim 8, wherein the coercive current at multiple temperatures are used to estimate whether the disk drive will fail at another temperature.

11. The hard disk drive of claim 1, wherein the peak current of the AC signal changes over time until the peak current is the coercive current.

12. A hard disk drive including:
a disk; and
a controller to cause the writing of a potion of the disk into a DC erased condition with magnetization in one direction, the controller causing an AC signal to be supplied to a write head over the disk, the AC signal being such to cause part of the portion to not have a significant direction of magnetization; wherein a characteristic of the supplied AC signal is used to determine whether to accept or reject the disk drive.

13. The hard disk drive of claim 12, wherein the characteristic is the peak current supplied to write head for the AC signal.

14. The hard disk drive of claim 13, wherein the peak current is the coercive current.

15. The hard disk drive of claim 14, wherein the coercive current at one temperature is used to estimate whether the disk drive will fail at another temperature.

16. The hard disk drive of claim 14, wherein the coercive current at multiple temperatures are used to estimate whether the disk drive will fail at another temperature.

17. The method of claim 12, wherein the peak current of the AC signal is changed over time until the peak current is the coercive current.

18. A current supply for a write head on a disk drive, the current supply having two modes, a first mode in which a first current range is supplied, the first current range being such that it includes a standard write current, the second current range being such that it includes a coercive current.

19. The current supply of claim 18, wherein a resistor portion can be controlled to switch between two resistor values to enable the first and second ranges.

20. A method of testing a disk drive comprising:
determining information related to the dynamic coercivity of a disk surface, the determining step including supplying an AC signal to a write head over the disk; and
using the information to accept or reject a disk drive.
